(19) United States
(12) Patent Application Publication
(10) Pub. No.: US 2007/0264590 A1
(43) Pub. Date: Nov. 15, 2007

(54) Patterning Process, Film Forming Process, Electroluminescence Device Manufacturing Process, Electroluminescence Device, and Electroluminescence Display Apparatus

(75) Inventor: Takashi Fukuchi, Chiba (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Tokyo (JP)

(21) Appl. No.: 11/663,537

(22) PCT Filed: Sep. 22, 2005
(86) PCT No.: PCT/JP05/18058

§ 371 Date: Mar. 22, 2007

Related U.S. Application Data
(60) Provisional application No. 60/614,326, filed on Sep. 30, 2004.
(60) Provisional application No. 60/690,922, filed on Jun. 16, 2005.

(30) Foreign Application Priority Data
Sep. 24, 2004 (JP) 2004-278158
Jun. 7, 2005 (JP) 2005-166848

(51) Int. Cl. G03F 7/00

(52) U.S. Cl. 430/139; 315/169.3

(57) ABSTRACT

Disclosed is a patterning process includes a patterning step including exposing a base to light, the base including: (a) a substrate; (b) a photocatalyst layer formed on part of the substrate and containing a photocatalyst; and (c) a patterning layer formed on an upper surface of a base including the substrate (a) and the photocatalyst layer (b), the patterning layer being decomposable by action of the photocatalyst; whereby the patterning layer on the photocatalyst layer (c) is decomposed and removed to expose at least part of an upper surface of the photocatalyst layer. According to this process, high-resolution and low-cost EL devices and electroluminescence display apparatuses are provided.

### CROSS REFERENCES OF RELATED APPLICATIONS

This application is an application filed under 35 U.S.C. §111 (a) claiming benefit pursuant to 35 U.S.C. §119(e) (1) of the filing dates of Provisional Application 60/614,326 filed Sep. 30, 2004 and Provisional Application 60/690,922 filed Jun. 16, 2005 pursuant to 35 U.S.C. §111(b).

### TECHNICAL FIELD

The present invention relates to patterning processes, film-forming processes, electroluminescence (hereinafter, also referred to as EL) device manufacturing processes, EL devices, and electroluminescence display apparatuses.

### BACKGROUND ART

Electroluminescence display apparatuses consist of many EL (electroluminescence) devices. Of the EL devices, for example organic EL devices have structures in which a transparent substrate such as glass is overlaid with a transparent lower electrode (anode) composed of ITO or the like, then with a luminescent layer (the luminescent layer used herein may be a laminate including a hole transport layer, an organic EL layer and an electron transport layer, wherein either or both of the hole transport layer and electron transport layer can be absent), and further with an upper electrode (cathode) composed of aluminum-lithium alloy, silver-magnesium alloy or silver-calcium alloy. The electroluminescence display apparatuses have an arrangement of many such EL devices, and display arbitrary images by causing appropriate EL devices to emit light in accordance with input signals. A great number of small EL devices emitting red (R), green (G) and blue (B) colors are arranged, and the emission intensities of the devices are controlled to display more colors.

Displaying higher-resolution images and more colors requires that the EL devices be smaller and be arranged in higher density. Photolithography is a general process for manufacturing minute devices, but the patterning of EL materials cannot involve the photolithography mainly in light of chemical stability of organic EL materials.

For example, Japanese Patent No. 1526026 (Patent Document 1) discloses a patterning process for EL materials in which the EL materials are deposited through a metal mask to form films. This process, however, requires repeating deposition for each of red, green and blue colors, and the use efficiency of the EL materials is low, not more than 1%. Further, precise alignment of a metal mask is difficult, and therefore the arrangement of many minute EL devices is limited. Accordingly, the resolution is limited to about 120 ppi (single pixel: 210 μm×70 μm), and 200 ppi resolution, which is considered an indication of high resolution, is impossible. Furthermore, the thermal expansion of the metal mask makes application to large substrates exceeding 300 mm on a side difficult. Moreover, the process entails an expensive deposition apparatus and limits the multiple image production in small-size EL display apparatuses, resulting in high production costs.

Japanese Patent No. 3036436 (Patent Document 2) discloses a process that comprises inkjetting a solution containing an EL material whereby tiny droplets are discharged and placed on predetermined positions to form a film. In this process, it is necessary that the droplets containing the EL material be placed on predetermined positions without mixing into adjacent pixel-forming positions. This limits the arrangement of many minute EL pixels particularly in light of droplet placement accuracy. Accordingly, the resolution is limited to about 140 ppi (single pixel: 180 μm×60 μm), and 200 ppi resolution is impossible as in the aforesaid deposition process. Furthermore, barriers must be provided between adjacent pixels for holding the placed droplets at the positions, increasing EL device manufacturing costs.

JP-A-2002-231446 (Patent Document 3) describes an EL device manufacturing process that comprises forming a photocatalyst layer on an electrode, forming a photodegradable organic layer on the photocatalyst layer, pattern exposing the photodegradable organic layer to decompose the same by photocatalytic action into a pattern, and forming an EL layer in the thus-formed pattern. This process, however, forms the photocatalyst layer on the entire surface of the substrate and therefore entails use of a photomask during light exposure. Furthermore, the radiation light that has passed through the photomask may undergo diffraction potentially deteriorating the patterning accuracy.

JP-A-2004-246027 (Patent Document 4) discloses a film-forming process that comprises a step comprising forming a lyophobic film on a treating surface of a substrate, a patterning step comprising removing part of the lyophobic film to form a lyophilic part, and a step comprising adding a liquid material to the lyophilic part to create a desired film. The patterning step performs electron beam exposure to increase the exposure accuracy.

[Patent Document 1] Japanese Patent No. 1526026

[Patent Document 2] Japanese Patent No. 3036436

[Patent Document 3] JP-A-2002-231446

[Patent Document 4] JP-A-2004-246027

### DISCLOSURE OF THE INVENTION

It is an object of the present invention to provide an easy, low-cost and high-accuracy process for forming desired pattern configurations.

It is another object of the invention to provide an easy, low-cost and high-accuracy process for producing films in desired pattern configurations.

It is a further object of the invention to provide an EL device enabling high resolution, an easy and low-cost manufacturing process for such EL devices, and an electroluminescence display apparatus including the EL devices.

The present inventor made intensive studies to solve the aforementioned problems and have completed the invention. The present invention concerns the following [1] to [17].

[1] A patterning process comprising a patterning step comprising exposing a base to light, the base comprising:

(a) a substrate;

(b) a photocatalyst layer formed on part of the substrate and containing a photocatalyst; and

(c) a patterning layer formed on an upper surface of a base comprising the substrate (a) and the photocatalyst layer (b), the patterning layer being decomposable by action of the photocatalyst;

whereby the patterning layer (c) on the photocatalyst layer (b) is decomposed and removed to expose at least part of an upper surface of the photocatalyst layer (b).

[2] The patterning process as described in [1], wherein the patterning layer (c) generates only a gaseous decomposition product upon the light exposure.

[3] The patterning process as described in [1] or [2], wherein the light exposure is performed by irradiation with an electromagnetic wave having energy equal to or greater than the bandgap of the photocatalyst.

[4] The patterning process as described in any one of [1] to [3], wherein the light exposure is performed by irradiation with an electromagnetic wave including ultraviolet light, an electromagnetic wave including ultraviolet light and visible light, or an electromagnetic wave including ultraviolet light and microwave.

[5] A film-forming process comprising:

(i) a step comprising forming a pattern by the patterning process as described in any one of [1] to [4]; and

(ii) a step comprising applying a liquid material to the exposed upper surface of the photocatalyst layer (b) and curing the liquid material to form a desired film (d).

[6] The film-forming process as described in [5], wherein the upper surface of the photocatalyst layer (b) has higher wettability with respect to the liquid material than the surface of the patterning layer (c).

[7] The film-forming process as described in [5] or [6], wherein the patterning layer (c) comprises a material including at least one compound that is liquid at room temperature and is selected from the group consisting of the following formulae (1) to (4):
G−CF₂−(CF₂)ₚ−CF₂−G (1)
G−(CF₂−CF₂−O)_{q}−(CF₂−O)ᵣ−G (2)
G−(CF₂−CF₂−O)ₛ−G (3)
G−(CF(CF₃)−CF₂−O)ₜ−(CF(CF₃)−O)ᵤ−G (4)
wherein G is independently F, CH₂—OH, CH(OH)—CH₂—OH, COOH, NH₂ or benzodioxol group; p is an integer ranging from 0 to 500; q and r are each an integer ranging from 0 to 100; s is an integer ranging from 1 to 200; and t and u are each an integer ranging from 0 to 100.

[8] The film-forming process as described in any one of [5] to [7], wherein the liquid material is applied by at least one technique selected from the group consisting of spin coating, dipping, spraying, inkjetting, printing and transferring.

[9] The film-forming process as described in any one of [5] to [8], further comprising a step (iii) comprising removing the remaining patterning layer (c) after the film-forming step (ii).

[10] The film-forming process as described in [9], wherein the step (iii) removes the patterning layer (c) by contacting a solution capable of dissolving the patterning layer (c) with the remaining patterning layer (c).

[11] An EL device manufacturing process for manufacturing EL devices having a structure comprising a substrate, a lower electrode as photocatalyst layer (b), a luminescent layer as film (d) and an upper electrode provided in this order, comprising forming the luminescent layer by the film-forming process as described in any one of [5] to [10].

[12] The EL device manufacturing process as described in [11], wherein the lower electrode comprises a material including at least one compound selected from the group consisting of titanium oxide, indium oxide, tin oxide and indium-tin oxide (ITO).

[13] The EL device manufacturing process as described in [11] or [12], wherein the liquid material is applied by inkjetting.

[14] The EL device manufacturing process as described in anyone of [11] to [13], wherein the upper electrode is formed by at least one technique selected from the group consisting of deposition, sputtering and printing.

[15] An EL device manufactured by the manufacturing process as described in any one of [11] to [14].

[16] The EL device as described in [15], wherein the substrate has a concave portion on the upper surface in which the lower electrode, the luminescent layer and the upper electrode are provided upward in this order.

[17] An electroluminescence display apparatus including the EL device as described in [15] or [16].

### EFFECT OF THE INVENTION

The patterning process of the present invention can create desired pattern configurations simply and inexpensively with high accuracy.

The film-forming process of the present invention can form films (layers) having a desired pattern configuration with high resolution and at low cost.

The EL device manufacturing process of the present invention can manufacture EL devices and electroluminescence display apparatuses with higher resolution and at lower cost than when the luminescent layer is produced by the conventional deposition or inkjetting technique. Further, the EL device manufacturing process of the invention can eliminate the need of barriers between pixels as required in the conventional inkjetting technique, and does not entail an expensive patterning apparatus such as a deposition apparatus.

### BRIEF DESCRIPTION OF THE DRAWINGS

FIG. 1 shows an embodiment of an EL device manufacturing process according to the present invention;

FIG. 2 shows an embodiment of an EL device manufacturing process according to the present invention;

FIG. 3 is a schematic view illustrating a structure of the electroluminescence devices manufactured in Example 1;

FIG. 4 is a schematic view illustrating a structure of the electroluminescence devices manufactured in Example 4; and

FIG. 5 is a schematic view illustrating a structure of the electroluminescence devices manufactured in Examples 5 and 6.
101 ITO lower electrode
102 Glass substrate
103 Lyophobic layer
104 ITO lower electrode surface
105 Hole transport layer (PEDT-PSS layer)
106 Red polymer EL layer
107 Green polymer EL layer
108 Blue polymer EL layer
109 Cathode layer
201 ITO lower electrode
202 Glass substrate
203 Hole transport layer (PEDT-PSS layer)
204 Red polymer EL layer
205 Green polymer EL layer
206 Blue polymer EL layer
207 Cathode layer
301 ITO lower electrode
302 Glass substrate
303 Hole transport layer (PEDT-PSS layer)
304 Red polymer EL layer
305 Cathode layer

### BEST MODE FOR CARRYING OUT THE INVENTION

The present invention will be described in detail hereinbelow.

### Patterning Process

The patterning process according to the present invention comprises a patterning step comprising exposing a base to light, the base comprising:

(a) a substrate;

(b) a photocatalyst layer formed on part of the substrate and containing a photocatalyst; and

(c) a patterning layer formed on an upper surface of a base comprising the substrate (a) and the photocatalyst layer (b), the patterning layer being decomposable by action of the photocatalyst;

whereby the patterning layer (c) on the photocatalyst layer (b) is decomposed and removed to expose at least part of an upper surface of the photocatalyst layer (b).

As used herein, the term “base” may mean a structure including a substrate and a layer on the substrate. For example, a substrate/photocatalyst layer structure may be referred to as the “base”, and a substrate/lower electrode/luminescent layer structure may be called the “base”.

(a) Substrate:

The substrate (a) may be selected appropriately depending on purpose without limitation as long as its surface permits formation of a photocatalyst layer. Materials of choice for light transmittance properties include transparent materials such as glasses, plastics and silicons, and for plasticity are resin materials and the like.

The area of the substrate is not particularly limited. According to the film-forming process of the invention described later, EL devices can be manufactured with high position accuracy even when the substrate is large, for example exceeding 300 mm on a side.

The thickness of the substrate is not particularly limited and may be selected appropriately depending on purpose.

(b) Photocatalyst Layer:

The photocatalyst layer (b) is formed on part of the substrate. Another layer may be provided between the substrate and the photocatalyst layer as required.

The photocatalyst layer (b) is composed of a material containing a photocatalyst. The photocatalyst is activated by irradiation with light to induce decomposition of neighboring substances.

Examples of the photocatalysts include semiconductor photocatalysts such as titanium oxide, indium oxide, tin oxide, indium-tin oxide (In₂₋ₓSnₓO₃ (ITO)), strontium titanate, tungsten oxide, bismuth oxide and iron oxide.

The photocatalyst layer (b) lies on partial regions of the substrate (a) and does not cover the entire surface of the substrate (a). This pattern of the photocatalyst layer (b) on the substrate (a) permits patterning of the patterning layer (c) in a shape similar to the pattern configuration of the photocatalyst layer (b) without a photomask, as described later.

The pattern configuration of the photocatalyst layer (b) is not particularly limited and may be any desired configuration. For example, the photocatalyst layer may have a pattern of not less than 200 ppi. The patterning of the photocatalyst layer may be performed by a known method.

The thickness of the photocatalyst layer is not particularly limited and may be selected appropriately. Because forming a uniform film is difficult when the thickness is too small, the lower limit of the thickness is preferably 1 nm, more preferably 10 nm. In the manufacturing of EL devices using the patterning process of the invention, the upper limit of the thickness is preferably 1000 nm, more preferably 200 nm because too large a thickness can make difficult the injection of charges from the lower electrode to the luminescent layer.

The surface roughness of the photocatalyst layer is not particularly limited and may be selected appropriately.

(c) Patterning Layer:

The patterning layer (c) is formed on the upper surface of the base including the substrate (a) and the photocatalyst layer (b). The patterning layer (c) is in contact with the upper surface of the photocatalyst layer (b) but is not necessarily in contact with the substrate (a), and a layer other than the photocatalyst layer (b) may be formed inbetween.

The patterning layer (c) is decomposable by action of the photocatalyst contained in the photocatalyst layer (b) when the photocatalyst has been activated by light exposure. The patterning layer (c) preferably consists solely of a compound that generates only a gaseous decomposition product when decomposed. The patterning layer (c) consisting solely of such a compound does not leave any decomposition product, and cleaning of such decomposition products after the patterning step can be omitted.

The thickness of the patterning layer (c) is not particularly limited, but is preferably in the range of 0.3 to 5 nm, more preferably in the range of 1 to 3 nm. The thickness not less than 0.3 nm permits formation of uniform layers, and the thickness not more than 5 nm enables the patterning layer (c) to be photodecomposed sufficiently.

The patterning layer (c) may be formed by any technique without particular limitation, with examples including spin coating, dipping and deposition.

In the patterning process of the invention, the base including the substrate (a), photocatalyst layer (b) and patterning layer (c) is exposed to light, whereby the patterning layer (c) on the upper surface of the photocatalyst layer is decomposed and removed to expose at least part of the upper surface of the photocatalyst layer (b).

The light exposure should involve light (electromagnetic wave) having energy equal to or greater than the bandgap energy of the photocatalyst. The intensity, irradiation angle, irradiation time and frequency may be determined appropriately. In addition to this electromagnetic wave, an electromagnetic wave having energy equal to or less than the bandgap energy of the photocatalyst may be applied simultaneously. Embodiments of the irradiation with the electromagnetic waves include irradiation with an electromagnetic wave including ultraviolet light, irradiation with an electromagnetic wave including ultraviolet light and visible light, and irradiation with an electromagnetic wave including ultraviolet light and microwave.

By the light exposure, the electromagnetic wave that has reached the photocatalyst layer (b) activates the photocatalyst, and the patterning layer (c) is decomposed by action of the photocatalyst. More specifically, the photocatalyst layer (b) produces a photocatalytic action to generate electrons and holes, and the patterning layer (c) on the photocatalyst layer (b) is decomposed.

Accordingly, the light exposure results in decomposition and removal of only the patterning layer (c) on the photocatalyst layer (b); the patterning layer (c) in other regions, that is, the patterning layer (c) found in regions other than on the photocatalyst layer (b) is not decomposed.

As described above, the patterning layer (c) exposes at least part of the upper surface of the photocatalyst layer (b) (hereinafter, also referred to as the exposed parts).

The patterning process of the present invention can decompose the patterning layer (c) on the photocatalyst layer (b) in a selective manner as described above even when the base is exposed to light without a photomask. Therefore, the process can pattern the patterning layer (c) with high accuracy in a configuration similar to the pattern configuration of the photocatalyst layer (b). Furthermore, the process does not require difficult alignment of a photomask, and thereby simplifies the patterning and reduces the patterning cost.

The light exposure may involve a photomask, in which case even if the electromagnetic wave applied undergoes diffraction to irradiate a region shadowed by the photomask (i.e., a region other than on the photocatalyst layer (b)), the patterning layer (c) found in this shadowed region is not decomposed and therefore no lowering is caused in resolution of pattern configurations. Furthermore, it is not necessary that the photomask be aligned with high precision, so that the patterning can be simplified and be accomplished at reduced costs.

### Film-Forming Process

The film-forming process according to the present invention comprises (i) a step comprising forming a pattern by the patterning process as described hereinabove (hereinafter, also referred to as the patterning step (i)); and (ii) a step comprising applying a liquid material to the exposed upper surface of the photocatalyst layer (b) and curing the liquid material to form a desired film (d) (hereinafter, also referred to as the film-forming step (ii)).

In the film-forming process of the invention, the patterning layer (c) preferably possesses both decomposability by action of the photocatalyst (photodecomposability) as described above, and lyophobicity (water and oil repellency). The patterning layer (c) preferably generates only a gaseous decomposition product when decomposed. As used herein, by “possessing lyophobicity (water and oil repellency)”, it is understood that the upper surface of the patterning layer (c) has lower wettability with respect to the liquid material (described later) than the surface of the photocatalyst layer (b).

With the patterning layer (c) possessing lyophobicity, the liquid material can be applied to the exposed upper surface (exposed parts) of the photocatalyst layer (b) without strict position control to form a film (d) at desired positions, because even if the liquid material protrudes to the surface of the patterning layer (c) neighboring the exposed parts, the liquid material that has protruded will spontaneously aggregate into the exposed parts. In other words, a desired film can be produced utilizing the difference in wettability between the surface of the photocatalyst layer (b) and the surface of the patterning layer (c). Accordingly, a high-resolution pattern of the film (d) can be formed from a desired material simply and inexpensively.

The materials of the patterning layer (c) possessing both photodecomposability and lyophobicity and generating only a gaseous decomposition product under action of the photocatalyst (i.e., the compounds capable of forming the patterning layer (c)) include compounds having a fluorocarbon main chain (hereinafter, also referred to as PFPE). Of such compounds, preferred are those compounds that are liquid at room temperature, for example 25° C., and are represented by any of the following formulae (1) to (4):
G−CF₂−(CF₂)ₚ−CF₂−G (1)
G−(CF₂−CF₂−O)_{q}−(CF₂−O)ᵣ−G (2)
G−(CF₂−CF₂−O)ₛ−G (3)
G−(CF(CF₃)−CF₂−O)ₜ−(CF(CF₃)−O)ᵤ−G (4)

In the formulae (1) to (4), G is independently F, CH₂—OH, CH(OH)—CH₂—OH, COOH, NH₂ or benzodioxol group.

The letter p is an integer ranging from 0 to 500, preferably from 2 to 400, more preferably from 10 to 100.

The letters q and r are each an integer ranging from 0 to 100, preferably from 2 to 100, more preferably from 5 to 80.

The letter s is an integer ranging from 1 to 200, preferably from 2 to 160, more preferably from 5 to 100.

The letters t and u are each an integer ranging from 0 to 100, preferably from 2 to 100, more preferably from 10 to 80.

Film-forming properties can be deteriorated and satisfactory films cannot be obtained in each of the cases where p exceeds 500, q exceeds 100, r exceeds 100, s exceeds 200, t exceeds 100 and u exceeds 100.

The above compounds preferably have molecular weight distributions (ratio of weight-average molecular weight (Mw) to number-average molecular weight (Mn):Mw/Mn) of 1.1 to 3.5, more preferably 1.6 to 2.5.

As used herein, the molecular weights of PFPE are in terms of polystyrene determined by gel permeation chromatography, and GPC conditions are as described below unless otherwise mentioned.

Chromatograph: HLC 8020 model manufactured by TOSOH CORPORATION

Columns: Ultra Styragel 103A&5×102A (manufactured by Waters Co.)

Mobile phase: Chlorofluorocarbon 113 (CF₂ClCFCl₂)

Flow rate: 1.0 ml/min

Detector: RI (differential refractometer)

Temperature: 35° C.

Sample quantity: 500 μl

Sample concentration: 0.1 wt % (Chlorofluorocarbon 113)

The compounds represented by the formulae (1) to (4) possess extremely high lyophobicity, and they exhibit high lyophobic properties even if the later-described liquid material for the film (d) is a high-polarity liquid such as water or a nonpolar solvent such as benzene. Moreover, these compounds have good film-forming properties and can give a film (patterning layer (c)) that is extremely thin (for example 0.3 nm thick), is free from defects and is continuous.

(ii) Film-Forming Step:

In the film-forming step (ii), the liquid material is applied to the exposed upper surface (exposed parts) of the photocatalyst layer (b) and is cured to form a desired film (d).

The liquid material may be prepared by dissolving in an appropriate solvent a material capable of forming a desired film (d). The solvent may be selected appropriately as long as it does not dissolve the photocatalyst layer (b) and the patterning layer (c) (hereinafter, also referred to as the lyophobic layer).

The techniques for application of the liquid material to the exposed parts include spin coating, dipping, spraying, inkjetting (hereinafter, also referred to as micro nozzle spraying), printing and transferring.

(iii) Patterning Layer-Removing Step

The film-forming process of the invention may include a patterning layer-removing step (iii) for removing the remaining patterning layer (c) after the film-forming step (ii). The remaining patterning layer (c) may be removed by contact with a solvent capable of dissolving the patterning layer (c). Specifically, the base may be soaked in an organic solvent capable of dissolving the patterning layer (c), or an organic solvent capable of dissolving the patterning layer (c) may be dropped on the base followed by spin cleaning. Examples of the organic solvents include perfluorooctane.

### EL Device Manufacturing Process

The EL device manufacturing process according to the present invention manufactures EL devices that have a structure including a substrate (a), a lower electrode as the photocatalyst layer (b), a luminescent layer as the film (d) and an upper electrode provided in this order, comprises forming the luminescent layer by the film-forming process as described above. That is, the luminescent layer is formed by the film-forming process as described above.

Specifically, the EL device manufacturing process produces the luminescent layer by the film-forming process comprising:

(i) a step comprising exposing a base to light, the base comprising:

a substrate (a);

a lower electrode formed on part of the substrate (a); and

the patterning layer (c) formed on an upper surface of a base comprising the substrate (a) and the lower electrode, the patterning layer being decomposable by photocatalytic action of the lower electrode;

whereby the patterning layer (c) on the lower electrode is decomposed and removed to expose at least part of an upper surface of the lower electrode; and

(ii) a step comprising applying a luminescent layer-forming liquid material to the exposed upper surface of the lower electrode and curing the liquid material to form a luminescent layer.

The EL device manufacturing process of the present invention can manufacture EL devices with higher resolution (for example 200 ppi) and at lower cost than by the conventional deposition or inkjetting technique. The EL device manufacturing process of the invention can also provide large EL devices, for example exceeding 300 mm on a side of substrate, with high resolution and at low cost.

In particular, the EL device manufacturing process can favorably provide active-matrix organic EL devices.

An embodiment of the organic EL device manufacturing process will be discussed below.

A lyophobic patterning layer (c) is formed on the upper surface of a substrate provided with circuits for driving EL devices and lower electrodes, that is, on the upper surface of a base including the substrate (a) and the lower electrodes formed on part of the substrate (a).

The lower electrode (anode) contains a photocatalyst and functions as the photocatalyst layer (b). Examples of the photocatalysts include titanium oxide, indium oxide (In₂O₃), tin oxide (SnO₂) and indium-tin oxide (ITO), with the indium-tin oxide (ITO) being preferable. The lower electrode is transparent or semitransparent, and is preferably transparent.

The lyophobic patterning layer (c) preferably consists solely of a compound having a fluorocarbon main chain, particularly a compound represented by any of the formulae (1) to (4).

When the base including the substrate (a), lower electrodes and patterning layer (c) is exposed to light, the lower electrodes function as semiconductor photocatalyst to produce electrons and holes, and the patterning layer on the lower electrodes is selectively decomposed and removed. The patterning layer is preferably decomposed to generate only a gaseous decomposition product and disappears from on the lower electrodes. Thus, lyophilic parts (exposed upper surface of the lower electrodes) are formed in the lyophobic patterning layer.

To the lyophilic parts, the luminescent layer-forming liquid material is applied, followed by drying to produce a luminescent layer. The luminescent layer may be of a single-layer type consisting of the organic EL layer, a two-layer type consisting of the organic EL layer and a hole transport layer or an electron transport layer, or a multi-layer type including the hole transport layer, organic EL layer and electron transport layer. The materials and thickness of these layers may be determined appropriately depending on purpose.

The luminescent layer of a single-layer type consisting of the organic EL layer may be fabricated by applying the organic EL layer-forming liquid material to the exposed parts and curing the liquid material.

The luminescent layer of a two-layer type consisting of, for example, the organic EL layer and hole transport layer may be fabricated by applying a hole transport layer-forming liquid material to the exposed parts followed by curing to form the hole transport layer, and forming the organic EL layer on the upper surface of the hole transport layer.

The hole transport layer-forming materials include diamines such as TPD (N,N′-diphenyl-N,N′-(3-methylphenyl)-1,1′-biphenyl-4,4′-diamine), phenylenediamines, oligoamines, spiroamines and dendrimer amines.

The organic EL layer-forming materials include luminescent materials such as anthracene materials, amine materials, styryl materials, silole materials, azole materials, polyphenyl materials and metal complex materials; and dopants such as dicyanomethylene pyran materials, dicyano materials, phenoxazone materials, thioxanthene materials, rubrene materials, styryl materials, coumarin materials, quinacridone materials, condensed polycyclic aromatic ring materials and heavy metal complex materials (such as [6-(4-biphenyl)-2,4-hexanedionato]bis(2-phenylpyridine) iridium (III)).

Specifically, the organic EL layer-forming materials include a mixture of poly(N-vinylcarbazole-co-[6-(4-vinylphenyl)-2,4-hexanedionato]bis(2-phenylpyridine)iridium (III)) (poly(VCz-co-IrPA)) and poly PBD;

a mixture of poly(N-vinylcarbazole-co-[6-(4-vinylphenyl)-2,4-hexanedionato]bis(3,5-difluoro-2-phenylpyridine) iridium (III)) (poly(VCz-co-IrPAF₂)) and poly PBD; and

a mixture of poly(N-vinylcarbazole-co-[6-(4-vinylphenyl)-2,4-hexanedionato]bis(3,3′,5,5′-tetrafluoro-2-phenylpyridine)iridium (III)) (poly(VCz-co-IrPAF₄)) and poly PBD.

Of these mixtures, the molar ratio of the monomeric unit of the components are as follows;

poly(VCz-co-IrPA):polyPBD is preferably 0.33-3:1, more preferably 1:1,

poly(VCz-co-IrPAF2):polyPBD is preferably 0.33-3:1, more preferably 1:1 and

poly(VCz-co-IrPAF4):polyPBD is preferably 0.33-3:1, more preferably 1:1.

The electron transport layer-forming materials include tris(8-quinolinolato)aluminum (III) and 2-biphenyl-5-(4-butylphenyl)-1,3,5-oxadiazole.

The luminescent layer-forming liquid material may be applied to the lyophilic parts by a technique such as spin coating, dipping, spraying or inkjetting. During the application, even if the luminescent layer-forming liquid material is brought into contact with the upper surface of the patterning layer (c) near the lyophilic parts, the liquid material is expelled automatically by the patterning layer (c) due to the strong lyophobicity (water and oil repellency) of the patterning layer (c) and spontaneously flows into the lyophilic parts whether the liquid material is an aqueous solution or an oily solution such as toluene or xylene. Accordingly, restrict control is not required of placement position of the liquid material, and no barriers partitioning the neighboring luminescent layer-forming regions are necessary. Therefore, a pattern of the luminescent layer can be produced with high resolution simply and inexpensively.

Drying the base provides the luminescent layer on the lower electrodes.

On the thus-formed luminescent layer is provided an upper electrode (cathode), and EL devices are manufactured.

The materials capable of forming the upper electrodes (cathodes) include aluminum-lithium alloy, silver-magnesium alloy and silver-calcium alloy.

The thickness of the upper electrodes is not particularly limited and may be selected appropriately.

The methods for producing the upper electrodes are not particularly limited and include deposition, printing and sputtering.

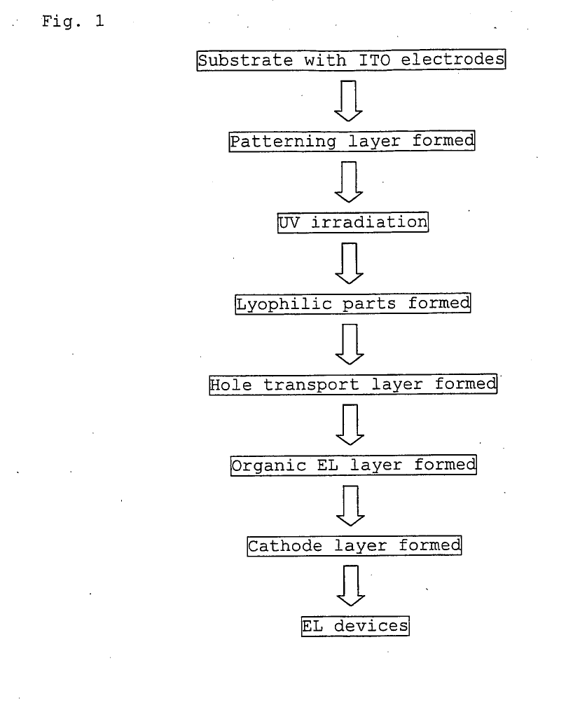

In an embodiment of the EL device manufacturing process according to the invention, the upper surface of all the lower electrodes may be exposed by one light exposure and the luminescent layer may be formed on the exposed parts. This exemplary EL device manufacturing process is indicated in FIG. 1.

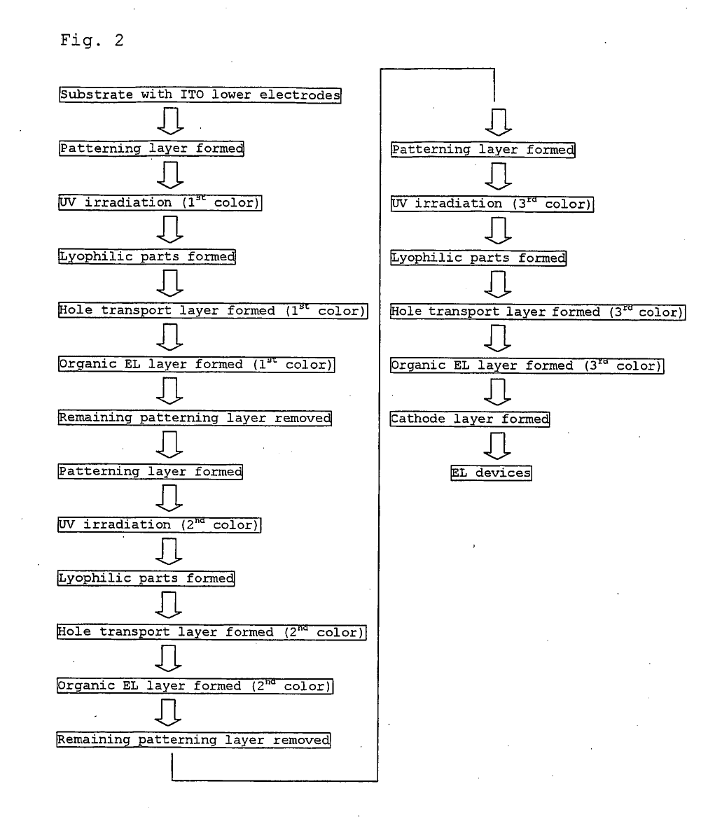

In another possible embodiment, the patterning layer may be formed and irradiated with light to expose regions for forming a luminescent layer of particular color, and the luminescent layer of particular color may be formed in the exposed parts followed by removing the remaining patterning layer; these steps are repeatedly performed for each of red, green and blue colors. This exemplary EL device manufacturing process is indicated in FIG. 2. The manufacturing process according to this embodiment involves a photomask for light exposing selected regions in which a luminescent layer of particular color is to be formed. The resolution of the photomask should be such that the lower electrodes other than under the luminescent layer-forming regions are not exposed to light.

Inkjetting is preferable for applying the liquid material to the exposed parts because the droplet placement position can be controlled with high accuracy to permit easy and high-accuracy placement of the red, green and blue liquid materials in appropriate positions.

### EL Devices

The EL devices, especially the active-matrix organic EL devices, according to the present invention include a substrate, a lower electrode on the substrate, a luminescent layer on the upper surface of the lower electrode, and an upper electrode on the luminescent layer, and are manufactured by the EL device manufacturing process as described above.

The EL devices of the invention are manufactured by the aforementioned EL device manufacturing process of the invention, that is, they can be produced with high resolution (for example 200 ppi or above), easily and inexpensively.

The upper surface of the substrate may have a concave portion in which the lower electrode, the luminescent layer and the upper electrode are provided upward. The depth of the concave portion may be in the range of 0.5 to 3 μm.

### Electroluminescence Display Apparatuses

The electroluminescence display apparatuses according to the present invention include the aforesaid EL devices of the invention. Accordingly, the electroluminescence display apparatuses provide effects similar to those achieved by the EL devices.

Specific examples of the electroluminescence display apparatuses include displays such as are used in cellular phones, mobile terminal devices, watches and clocks, personal computers, word processors and game machines.

### EXAMPLES

The present invention will be described in further detail by discussing embodiments of production of EL display apparatuses having active-matrix and bottom emission EL devices. However, it should be construed that the invention is not limited thereto.

The following examples employed:

a red polymer EL layer-forming material that was a mixture of poly(N-vinylcarbazole-co-[6-(4-vinylphenyl)-2,4-hexanedionato]bis(2-phenylpyridine)iridium (III)) (poly(VCz-co-IrPA)) and poly PBD (hereinafter, also referred to as the red EL material);

a green polymer EL layer-forming material that was a mixture of poly(N-vinylcarbazole-co-[6-(4-vinylphenyl)-2,4-hexanedionato]bis(3,5-difluoro-2-phenylpyridine) iridium (III)) (poly(VCz-co-IrPAF₂)) and poly PBD (hereinafter, also referred to as the green EL material); and

a blue polymer EL layer-forming material that was a mixture of poly(N-vinylcarbazole-co-[6-(4-vinylphenyl)-2,4-hexanedionato]bis(3,3′,5,5′-tetrafluoro-2-phenylpyridine)iridium (III)) (poly(VCz-co-IrPAF₄)) and poly PBD (hereinafter, also referred to as the blue EL material).

### Example 1

<Formation of Luminescent Layer by Dipping and Transferring>

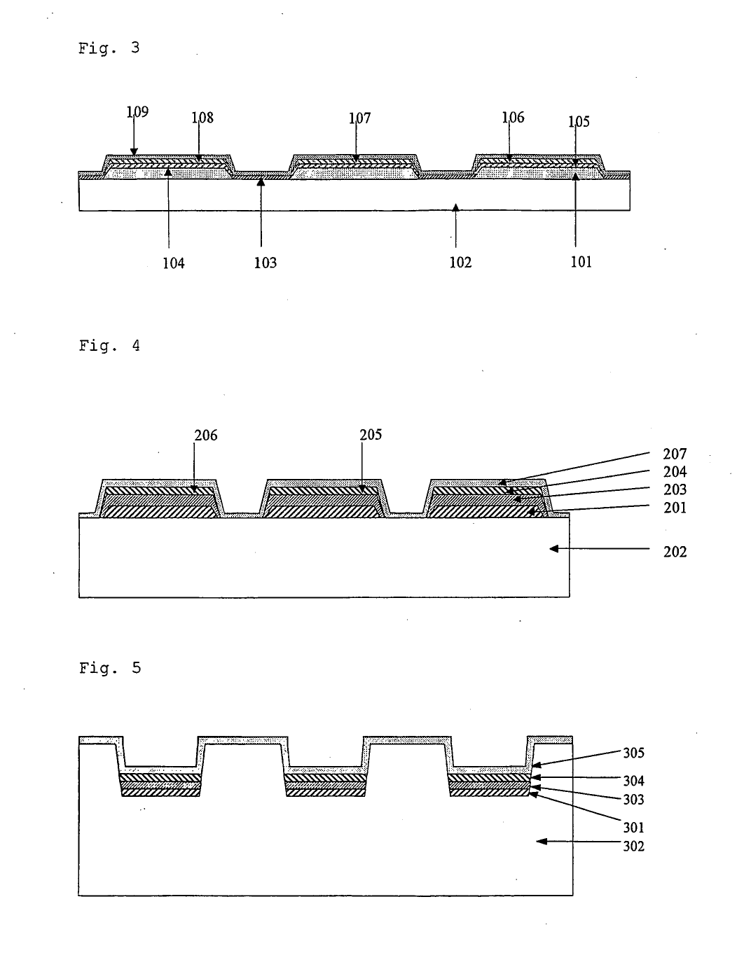

The following description is made with reference to FIG. 3.

A glass substrate 102 (500 mm×500 mm, 0.7 mm thick) was provided on which circuits for driving active-matrix EL devices and ITO lower electrodes 101 (61.0 μm×37.3 μm, 0.1 μm thick) arranged in a pattern were formed (the between-electrode distances were 66.0 μm in electrode longer side direction and 5 μm in electrode shorter side direction). On the entire upper surface of the glass substrate (that is, on the exposed substrate surface and the lower electrode pattern surface, the same applies hereinafter), a patterning layer-forming material G-CF₂—(CF₂)ₚ—CF₂-G (a mixture of molecules in which G is F and p=0-500; product name: DEMNUM SP (manufactured by DAIKIN INDUSTRIES, LTD.)) (hereinafter, also referred to as PFPE 1) was deposited to form a PFPE 1 pattering layer (PFPE 1 layer) 103 having a thickness of 2 nm. The entire surface of the thus-produced base was then irradiated with UV light of 290 nm center wavelength (70 mW/cm²) from the PFPE 1 layer side for 5 minutes without a photomask. The PFPE 1 layer 103 was decomposed in selected regions on the ITO lower electrodes 101, and these regions disappeared to expose an ITO surface 104.

Subsequently, a hole transport layer 105 was produced by dipping. Specifically, a solution bath was charged with 500 ml of an aqueous solution (concentration: 1.0 wt %) of poly(3,4-ethylenedioxythiophene)/polystyrene sulfonate copolymer (hereinafter, also referred to as PEDT-PSS). Thereafter, the base was soaked in the solution and was lifted vertically at a rate of 10 mm/min, and the aqueous PEDT-PSS solution was attached selectively to the ITO surface 104. The base was then dried at 150° C. under reduced pressure for 1 hour. Thus, a 50 nm thick hole transport layer 105 of PEDT-PSS was formed on the ITO surface 104.

Next, organic EL layers, namely, a red polymer EL layer 106, a green polymer EL layer 107 and a blue polymer EL layer 108 were provided by transferring.

Specifically, the red EL material was formed into a film (hereinafter, also referred to as the red EL film) in a thickness such that the dry thickness would be 50 nm, on one surface of a plastic film having an absorption maximum at 830 nm. The surface of the red EL film on the plastic film was stuck to a surface of PEDT-PSS layer being a red EL device-forming region on the substrate. The PEDT-PSS layer was irradiated with a laser beam (830 nm, 10 mW) through the plastic film for 0.001 second per pixel, and the red EL film on the plastic film surface was transferred to the PEDT-PSS layer. Thereafter, the green EL material was formed into a film (hereinafter, also referred to as the green EL film) in a thickness such that the dry thickness would be 50 nm, on one surface of a plastic film having an absorption maximum at 830 nm. The surface of the green EL film on the plastic film was stuck to a surface of PEDT-PSS layer being a green EL device-forming region on the substrate. The green EL film was transferred to the PEDT-PSS layer under the conditions as described above. Subsequently, the blue EL material was formed into a film (hereinafter, also referred to as the blue EL film) in a thickness such that the dry thickness would be 50 nm, on one surface of a plastic film having an absorption maximum at 830 nm. The surface of the blue EL film on the plastic film was stuck to a surface of PEDT-PSS layer being a blue EL device-forming region on the substrate. The blue EL film was transferred to the PEDT-PSS layer under the conditions as described above. The base was then dried at 80° C. under reduced pressure in a nitrogen atmosphere for 1 hour, and a red EL layer 106, a green EL layer 107 and a blue EL layer 108 each 50 nm thick were formed.

Subsequently, a 100 nm thick upper electrode layer (cathode layer) 109 of silver-calcium alloy was sputtered on each of the EL layers, and EL devices were manufactured.

### Example 2-1

<Formation of Luminescent Layer by Inkjetting (Micro Nozzle Spraying)>

A glass substrate with ITO lower electrodes as used in Example 1 was provided. With use of a dropping pipette, 20 ml of a perfluorooctane solution (concentration: 0.024%) of a patterning layer-forming material G−(CF₂−CF₂−O)_{q}−(CF₂−O)ᵣ−G (a mixture of molecules in which G is CH₂—OH and q=0-100 and r=0-100; product name: Fomblin Z-DOL (manufactured by Monti Edison in Italy)) (hereinafter, also referred to as PFPE 2) was dropped on the entire upper surface of the glass substrate. The base was then high-speed rotated at 1000 rpm and was dried at 100° C. for 1 hour to form a 2 nm thick patterning layer of PFPE 2. The entire surface of the base was then irradiated with UV light of 340 nm center wavelength (70 mW/cm²) from the PFPE 2 layer side for 30 minutes without a photomask. The PFPE 2 layer was decomposed in selected regions on the ITO lower electrodes 101, and these regions disappeared to expose an ITO lower electrode surface 104.

Subsequently, a hole transport layer 105 was produced by micro nozzle spraying. Specifically, an aqueous PEDT-PSS solution (concentration: 1.0 wt %) was sprayed from micro nozzles of a commercially available inkjet printer to the exposed ITO surface 104. The base was then dried at 150° C. under reduced pressure for 1 hour to produce a 50 nm thick hole transport layer 105.

In the above micro nozzle spraying, the aqueous PEDT-PSS solution was sprayed without precise control of the droplet placement position, so that the droplets were placed also around regions where they should be applied (hereinafter, also referred to as the applying regions). But these droplets spontaneously moved to the applying regions.

Thereafter, organic EL layers, namely, a red polymer EL layer 106, a green polymer EL layer 107 and a blue polymer EL layer 108 were produced.

Specifically, a tetralin solution of the red EL material (concentration: 1.0 wt %) was sprayed from micro nozzles to a surface of PEDT-PSS layer being a red EL device-forming region on the substrate. Thereafter, a tetralin solution of the green EL material (concentration: 1.0 wt %) was sprayed from micro nozzles to a surface of PEDT-PSS layer being a green EL device-forming region on the substrate. Next, a tetralin solution of the blue EL material (concentration: 1.0 wt %) was sprayed from micro nozzles to a surface of PEDT-PSS layer being a blue EL device-forming region on the substrate. The base was then dried at 80° C. under reduced pressure in a nitrogen atmosphere for 1 hour, and a red EL layer 106, a green EL layer 107 and a blue EL layer 108 each 50 nm thick were formed.

In the above micro nozzle spraying, the tetralin solutions of the red, green and blue EL materials were sprayed without precise control of the droplet placement position, so that the droplets were placed also around the applying regions. But these droplets spontaneously moved to the applying regions.

Subsequently, a 100 nm thick cathode layer 109 of magnesium-silver alloy was deposited on each of the EL layers, and EL devices were manufactured.

### Example 2-2

EL devices were manufactured in the same manner as in Example 2-1, except the patterning layer was formed from G−(CF₂−CF₂−O)_{q}−(CF₂−O)ᵣ−G (a mixture of molecules in which G is benzodioxol group and q=0-100 and r=0-100; product name: Fomblin AM2001 (manufactured by Monti Edison in Italy)).

### Example 3-1

<Formation of Luminescent Layer by Spraying and Printing>

A glass substrate with ITO lower electrodes as used in Example 1 was provided. With use of a dropping pipette, 20 ml of a perfluorooctane solution (concentration: 0.024%) of a patterning layer-forming material G−(CF₂−CF₂−O)ₛ−G (a mixture of molecules in which G is COOH and s=1-200; product name: DEMNUM SA (manufactured by DAIKIN INDUSTRIES, LTD.)) (hereinafter, also referred to as PFPE 3) was dropped on the entire upper surface of the glass substrate. The base was then high-speed rotated at 1000 rpm and was dried at 100° C. for 1 hour to form a 2 nm thick patterning layer of PFPE 3. The entire surface of the base was then irradiated with UV light of 340 nm center wavelength (70 mW/cm²) from the PFPE 3 layer side for 15 minutes without a photomask. The PFPE 3 layer was decomposed in selected regions on the ITO lower electrodes 101, and these regions disappeared to expose an ITO lower electrode surface 104.

Subsequently, a hole transport layer 105 was produced by spraying. Specifically, an aqueous PEDT-PSS solution (concentration: 1.0 wt %) was sprayed in the form of a mist from spray nozzles to the upper surface of the base. The base was then high-speed rotated at 1000 rpm, and the aqueous PEDT-PSS solution found in regions other than the exposed ITO lower electrode surface 104 was eliminated. The base was thereafter dried at 150° C. for 1 hour to produce a 50 nm thick hole transport layer 105.

Thereafter, organic EL layers, namely, a red polymer EL layer 106, a green polymer EL layer 107 and a blue polymer EL layer 108 were produced by printing.

Specifically, the red EL material was dissolved in tetramethylbenzene to give a red EL ink with 5.5 wt % concentration. On the base was overlaid a screen capable of passing the red EL ink selectively to a surface of PEDT-PSS layer being a red EL device-forming region on the substrate, and the red EL ink was printed over the screen. The base was then dried at 100° C. under reduced pressure in a nitrogen atmosphere for 2 hours, and a 50 nm thick red EL layer 106 was formed. A green EL layer 107 and a blue EL layer 108 each 50 nm thick were formed in a similar manner on predetermined regions of the PEDT-PSS layer surface.

Subsequently, a 100 nm thick cathode layer 109 of lithium-aluminum alloy was deposited on each of the EL layers, and EL devices were manufactured.

### Example 3-2

EL devices were manufactured in the same manner as in Example 3-1, except the patterning layer was formed from G−(CF(CF₃)−CF₂−O)_{q}−(CF(CF₃)−O)ᵣ−G (a mixture of molecules in which G is NH₂ and q=0-100 and r=0-100; product name: Krytox SX manufactured by DuPont, USA).

### Example 4

<Formation of Luminescent Layer by Dipping and Transferring>

The following description is made with reference to FIG. 4.

A glass substrate 202 was provided on which ITO lower electrodes 201 were arranged in a pattern similar to that of Example 1. With use of a dropping pipette, 20 ml of a perfluorooctane solution (concentration: 0.024%) of a patterning layer-forming material G−(CF(CF₃)−CF₂−O)ₜ−(CF(CF₃)−O)ᵤ−G (a mixture of molecules in which G is CH₂—OH and t=0-100 and u=0-100; product name: Krytox GX manufactured by DuPont, USA) (hereinafter, also referred to as PFPE 4) was dropped on the entire upper surface of the glass substrate. The base was then high-speed rotated at 1000 rpm and was dried at 100° C. for 1 hour to form a 2 nm thick patterning layer of PFPE 4 (PFPE 4 layer). The entire surface of the base was then irradiated with UV to visible light of 290 nm center wavelength and 400 nm long-wave end (70 mW/cm²) from the PFPE 4 layer side for 5 minutes through a photomask so as to irradiate only red EL device-forming regions. The PFPE 4 layer was decomposed selectively in the red EL device-forming regions on the ITO lower electrodes 201, and these regions disappeared to expose an ITO lower electrode surface.

Subsequently, a hole transport layer (PEDT-PSS layer) 203 was produced on the exposed ITO lower electrode surface by dipping. Specifically, a solution bath was charged with 100 ml of a 0.5 wt % aqueous PEDT-PSS solution, and the base was soaked in the solution and was lifted vertically at a rate of 10 mm/min. Thus, a hole transport layer 203 having a thickness of 10 nm was formed.

Next, an organic EL layer, namely, a red polymer EL layer 204 was provided by transferring.

Specifically, the red EL material was formed into a film (hereinafter, also referred to as the red EL film) in a thickness such that the dry thickness would be 20 nm, on one surface of a plastic film having an absorption maximum at 830 nm. The surface of the red EL film on the plastic film was stuck to a surface of PEDT-PSS layer 204 on the substrate. The PEDT-PSS layer was irradiated with a laser beam (830 nm, 10 mW) through the plastic film for 0.1 second per pixel, and the red EL film on the plastic film surface was transferred to the PEDT-PSS layer. Thereafter, drying was performed at 60° C. for 1 hour to obtain a 20 nm thick red polymer EL layer 204. The base was then cleaned by contacting the entire surface thereof with perfluorooctane for 10 minutes to remove the remaining PFPE 4 layer.

Subsequently, a green polymer EL layer 205 was formed as described below. With use of a dropping pipette, 20 ml of a perfluorooctane solution of PFPE 4 (concentration: 0.024%) was dropped on the base so as to cover the entire surface of the base on which the red polymer EL layer 204 had been formed. The base was then high-speed rotated under the same conditions as described for the red polymer EL layer 204, and a 2 nm thick patterning layer (PFPE 4 layer) was produced. The entire surface of the base was then irradiated with UV to visible light of 290 nm center wavelength and 400 nm long-wave end (70 mW/cm²) from the PFPE 4 layer side for 5 minutes through a photomask so as to irradiate only green EL device-forming regions. The PFPE 4 layer was decomposed selectively in the green EL device-forming regions on the ITO lower electrodes 201, and these regions disappeared to expose an ITO lower electrode surface.

Subsequently, a 10 nm thick hole transport layer 203 was formed under the same conditions as described for the red polymer EL layer 204.

A 20 nm thick green polymer EL layer 205 was produced in green EL device-forming regions under the same conditions as described for the red polymer EL layer 204 except using the green EL material as organic EL material. The base was then cleaned by contacting the entire surface thereof with perfluorooctane for 10 minutes to remove the remaining PFPE 4 layer.

Subsequently, a blue polymer EL layer 206 was formed as described below. With use of a dropping pipette, 20 ml of a perfluorooctane solution of PFPE 4 (concentration: 0.024%) was dropped on the base so as to cover the entire surface of the base on which the red polymer EL layer 204 and green polymer EL layer 205 had been formed. The base was then high-speed rotated under the same conditions as described for the red polymer EL layer 204, and a 2 nm thick patterning layer (PFPE 4 layer) was produced. The entire surface of the base was then irradiated with UV to visible light of 290 nm center wavelength and 400 nm long-wave end (70 mW/cm²) from the PFPE 4 layer side for 5 minutes through a photomask so as to irradiate only blue EL device-forming regions. The PFPE 4 layer was decomposed selectively in the blue EL device-forming regions on the ITO lower electrodes 201, and these regions disappeared to expose an ITO lower electrode surface.

Subsequently, a 10 nm thick hole transport layer 203 was formed under the same conditions as described for the red polymer EL layer 204.

Thereafter, a 20 nm thick blue polymer EL layer 206 was produced in blue EL device-forming regions under the same conditions as described for the red polymer EL layer 204 except using the blue EL material as organic EL material. The base was then cleaned by contacting the entire surface thereof with perfluorooctane for 10 minutes to remove the remaining PFPE 4 layer.

Subsequently, a 100 nm thick cathode layer 207 of silver-calcium alloy was sputtered on each of the EL layers, and EL devices were manufactured.

### Example 5

<Formation of Luminescent Layer by Dipping and Transferring>

The following description is made with reference to FIG. 5.

A glass substrate 302 was provided on which circuits for driving active-matrix EL devices and ITO lower electrodes 301 (61.0 μm×37.3 μm, 0.1 μm thick) arranged in a pattern were formed (the between-electrode distances were 66.0 μm in electrode longer side direction and 5 μm in electrode shorter side direction). A luminescent layer was produced on the glass substrate 302 as follows. In the upper surface of the substrate 302, there were concave portions (61.0 μm×37.3 μm, 2 μm deep) similar in shape to the pattern of the ITO electrodes, and the ITO electrodes were in the respective concave portions.

A patterning layer-forming material G−(CF₂−CF₂−O)ₚ−(CF₂−O)_{q}−G (a mixture of molecules in which G is COOH and p=0-100 and q=0-100; product name: Fomblin DIAC (manufactured by Monti Edison in Italy)) (hereinafter, also referred to as PFPE 5) was formed into a pattering layer (PFPE 5 layer) by spin coating. Specifically, 5 ml of a perfluorooctane solution of PFPE 5 (concentration: 0.01%) was dropped from a dropping pipette onto the base, and the base was high-speed rotated at 1000 rpm and was dried at 60° C. for 1 hour to obtain a 2 nm thick patterning layer of PFPE 5.

The base was then irradiated with UV light and microwave (24.5 GHz) from the PFPE 5 layer side for 1 minute through a photomask so as to irradiate only red EL layer-forming regions. The PFPE 5 layer was decomposed selectively in the red EL layer-forming regions on the ITO lower electrodes 301, and these regions disappeared to expose an ITO lower electrode surface.

Subsequently, a hole transport layer (PEDT-PSS layer) 303 and a red polymer EL layer 304 were formed on the exposed ITO lower electrode surface by the same procedures as described in Example 4. The base was then cleaned by contacting the entire surface thereof with perfluorooctane for 10 minutes to remove the remaining PFPE 5 layer.

Subsequently, a hole transport layer and a green polymer EL layer were produced on green EL layer-forming regions, and the remaining PFPE 5 layer was removed by the same procedures as described for the red polymer EL layer 304. Thereafter, a hole transport layer and a blue polymer EL layer were produced on blue EL layer-forming regions, and the remaining PFPE 5 layer was removed by the same procedures as described for the red polymer EL layer 304.

Subsequently, a 100 nm thick cathode layer 305 of silver-calcium alloy was sputtered on each of the EL layers, and EL devices were manufactured.

### Example 6

<Formation of Luminescent Layer by Dipping and Transferring>

EL devices were manufactured in the same manner as in Example 5, except the patterning layer was formed from G−(CF₂−CF₂−O)ₛ−G (a mixture of molecules in which G is COOH and s=1-200; product name: DEMNUM SA (manufactured by DAIKIN INDUSTRIES, LTD.)) (hereinafter, also referred to as PFPE 6).

All the EL devices manufactured in Examples 1 to 6 had a high resolution of 200 ppi and an aperture ratio of 50%.

### INDUSTRIAL APPLICABILITY

The patterning processes and film-forming processes according to the present invention enable high-resolution, easy and low-cost manufacturing of EL devices and the like. The EL devices of the invention have a high resolution and are producible easily and inexpensively, and therefore the invention can favorably provide electroluminescence display apparatuses such as displays in cellular phones, mobile terminal devices, watches and clocks, personal computers, word processors and game machines.

1. A patterning process comprising a patterning step comprising exposing a base to light, the base comprising:
(a) a substrate;
(b) a photocatalyst layer formed on part of the substrate and containing a photocatalyst; and
(c) a patterning layer formed on an upper surface of a base comprising the substrate (a) and the photocatalyst layer (b), the patterning layer being decomposable by action of the photocatalyst;
whereby the patterning layer (c) on the photocatalyst layer (b) is decomposed and removed to expose at least part of an upper surface of the photocatalyst layer (b).

2. The patterning process according to claim 1, wherein the patterning layer (c) generates only a gaseous decomposition product upon the light exposure.

3. The patterning process according to claim 1, wherein the light exposure is performed by irradiation with an electromagnetic wave having energy equal to or greater than the bandgap of the photocatalyst.

4. The patterning process according to claim 1, wherein the light exposure is performed by irradiation with an electromagnetic wave including ultraviolet light, an electromagnetic wave including ultraviolet light and visible light, or an electromagnetic wave including ultraviolet light and microwave.

5. A film-forming process comprising:
(i) a step comprising forming a pattern by the patterning process as described in claim 1; and
(ii) a step comprising applying a liquid material to the exposed upper surface of the photocatalyst layer (b) and curing the liquid material to form a desired film (d).

6. The film-forming process according to claim 5, wherein the upper surface of the photocatalyst layer (b) has higher wettability with respect to the liquid material than the surface of the patterning layer (c).

7. The film-forming process according to claim 5, wherein the patterning layer (c) comprises a material including at least one compound that is liquid at room temperature and is selected from the group consisting of the compounds represented by the following formulae (1) to (4):
G−CF₂−(CF₂)ₚ−CF₂−G (1)
G−(CF₂−CF₂−O)_{q}−(CF₂−O)ᵣ−G (2)
G−(CF₂−CF₂−O)ₛ−G (3)
G−(CF(CF₃)−CF₂−O)ₜ−(CF(CF₃)−O)ᵤ−G (4)
wherein G is independently F, CH₂—OH, CH(OH)—CH₂—OH, COOH, NH₂ or benzodioxol group; p is an integer ranging from 0 to 500; q and r are each an integer ranging from 0 to 100; s is an integer ranging from 1 to 200; and t and u are each an integer ranging from 0 to 100.

8. The film-forming process according to claim 5, wherein the liquid material is applied by at least one technique selected from the group consisting of spin coating, dipping, spraying, inkjetting, printing and transferring.

9. The film-forming process according to claim 5, further comprising a step (iii) comprising removing the remaining patterning layer (c) after the film-forming step (ii).

10. The film-forming process according to claim 9, wherein the step (iii) removes the patterning layer (c) by contacting a solution capable of dissolving the patterning layer (c) with the remaining patterning layer (c).

11. An EL device manufacturing process for manufacturing EL devices having a structure comprising a substrate, a lower electrode as photocatalyst layer (b), a luminescent layer as film (d) and an upper electrode provided in this order, comprising forming the luminescent layer by the film-forming process as described in claim 5.

12. The EL device manufacturing process according to claim 11, wherein the lower electrode comprises a material including at least one compound selected from the group consisting of titanium oxide, indium oxide, tin oxide and indium-tin oxide (ITO).

13. The EL device manufacturing process according to claim 11, wherein the liquid material is applied by inkjetting.

14. The EL device manufacturing process according to claim 11, wherein the upper electrode is formed by at least one technique selected from the group consisting of deposition, sputtering and printing.

15. An EL device manufactured by the manufacturing process as described in claim 11.

16. The EL device according to claim 15, wherein the substrate has a concave portion on the upper surface in which the lower electrode, the luminescent layer and the upper electrode are provided upward in this order.

17. An electroluminescence display apparatus including the EL device as described in claim 15.
